(19) United States
(12) Patent Application Publication
(10) Pub. No.: US 2019/0237645 A1
(43) Pub. Date: Aug. 1, 2019

(54) CONVERSION MODULE WITH LEAD FRAME

(71) Applicant: OSRAM GmbH, Munich (DE)

(72) Inventors: Georg Forster, Sinzing (DE); Moritz Engl, Regensburg (DE)

(21) Appl. No.: 16/258,683

(22) Filed: Jan. 28, 2019

(30) Foreign Application Priority Data
Jan. 30, 2018 (DE) 10 2018 201 425.6

(51) Int. Cl. H01L 33/62

(52) U.S. Cl. CPC H01L 33/62; H01L 2933/0066

(57) ABSTRACT

A conversion module for a conversion lamp includes a lead frame; and a conversion element received in the lead frame.

### CROSS-REFERENCE TO RELATED APPLICATION

This application claims priority to German Patent Application Serial No. 10 2018 201 425.6, which was filed Jan. 30, 2018, and is incorporated herein by reference in its entirety.

### TECHNICAL FIELD

Various embodiments relate generally to a conversion module for a conversion lamp having a conversion element.

### BACKGROUND

A conventional conversion lamp may be a lamp including so-called LARP technology. The technical acronym LARP stands for Laser Activated Remote Phosphor. The converter is in this case often exposed to high temperatures or thermal energy inputs. This is due on the one hand to the energy of the radiation incident on the converter and on the other hand to the conversion process per se, since the radiation is in this case partially absorbed by the conversion element, or the converter, and wavelength-converted, wherein during the conversion of high-energy radiation into radiation with lower energy (longer wavelength) a part of the energy is converted into heat (“Stokes shifted”). The converter includes and/or consists of a conversion material, or a conversion substance, or a phosphor. Often, conversion substances are used in which the conversion efficiency depends on the temperature (heating) and decreases with higher temperatures; this is also referred to as thermal quenching or thermal rollover. This leads—with given construction space requirements, optical requirements in relation to a radiation concentration and/or cost requirements in relation to the amount and/or size of the conversion material used—to a thermal dissipation requirement.

In conversion lamps having a high radiant intensity, a laser, that is to say collimated, i.e. concentrated or directed, radiation with a high beam density, is often used as excitation radiation. A safety measure is therefore to be taken so that the laser radiation with a high beam density does not emerge in a concentrated form, but at worst as scattered radiation, so that for example damage to a person does not occur (eye, skin). To this end, it is known to provide feedback control, such as providing a so-called active SRS safety sensor (SRS=Safety Recognition Sensor), which detects the integrity of the converter and, in the event of damage, prevents generation of the laser excitation radiation or minimizes its radiation power. Although this feedback control entails an application-dependently significant safety benefit, on the other hand it entails increased outlay in terms of design and production.

### SUMMARY

A conversion module for a conversion lamp includes a lead frame; and a conversion element received in the lead frame.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a perspective exploded view of a conventional conversion lamp;

FIG. 2 shows a perspective plan view of a conversion element according to various embodiments in a round configuration according to a first embodiment;

FIG. 3 shows a perspective plan view of a conversion element according to various embodiments in a polygonal configuration according to a second embodiment;

FIG. 4 shows a perspective view from below of the conversion element of FIG. 3;

FIG. 5 shows a sectional representation of a conversion module according to a third embodiment;

FIG. 6 shows a plan view of the conversion module of FIG. 5;

FIG. 7 shows a sectional representation of a conversion module according to a fourth embodiment;

FIG. 8 shows a plan view of the conversion module of FIG. 7;

FIG. 9 shows a sectional representation of a conversion module according to a fifth embodiment; and

FIG. 10 shows a perspective plan view of the conversion module of FIG. 9.

### DESCRIPTION

The following detailed description refers to the accompanying drawings that show, by way of illustration, specific details and embodiments in which the invention may be practiced.

The figures are merely schematic in nature and serve only for understanding the embodiments. Elements which are the same are provided with the same features throughout the figures and embodiments. A repeated description of features which are the same is mostly omitted. Features of one embodiment may also be contained in the other embodiment, i.e. they are interchangeable with one another, even partially.

Conversion lamps of the type introduced above are a series product. Various embodiments allow to manufacture conversion modules reliably in terms of process and/or with low outlay. Further aspects of series production, such as low costs or suitability for high batch numbers, may be taken into consideration.

Various embodiments provide a conversion module which is suitable for use in/on a conversion lamp. The conversion module contains or consists of at least one conversion element, or a converter. The conversion element may be configured for at least partial conversion, for instance wavelength conversion, of excitation radiation into conversion radiation. By reception of the conversion element in a lead frame, as it is known in the art, the handleability of the conversion element is improved. In various embodiments, it becomes possible to incorporate the processes relating to the conversion element into manufacturing methods which are known from semiconductor fabrication and, for example, are carried out in a clean room. The lead frame may, in an economical embodiment, be a frame without terminals. The lead frame may be provided for reception in a holder or mount, to which end for example an insertion chamfer, a rigid configuration, etc. may be provided. The lead frame may be characterized by a standardized form, for example a form suitable for different conversion elements and/or conversion element formats, which may itself be economical and/or for which economical tools may be available. The lead frame may replace a substrate, for instance an expensive sapphire glass, as the element stabilizing a conversion element, so that a sapphire-less or substrate-less design may be economically implemented.

The term conversion material refers to optical and/or physical-material properties, for instance a color, a conversion behavior, a thermal conductivity and the like. In the context of this description, the term conversion element preferably refers to concrete and/or technical-material properties, such as a shape or geometrical dimensions, a format, a rigidity and the like. The conversion element includes a phosphor as conversion material, it also being possible for the “phosphor” to be a phosphor mixture of a plurality of individual phosphors. One individual phosphor may be cerium-doped yttrium aluminum garnet (YAG:Ce), then with yellow light as conversion radiation. In general, however, as an alternative or in addition another or other individual phosphor(s) are also possible, for instance for emitting red and/or green conversion light, although another yellow phosphor may also be envisioned.

The term conversion module, on the other hand, refers to a superordinate design unit including at least the conversion element and the lead frame. Although the conversion module is referred to as a module, this term does not conflict with a one-piece design of the conversion module.

The conversion module may include a sensor which is applied onto the conversion element. The sensor is at least one sensor part, or sensor section.

The sensor may be a measurement path, or a passive part of a sensor device including a measurement path (passive part) and a measuring transducer (active part) that may be provided separately. The sensor may be configured in order to make a break of the conversion element detectable, for instance making the break of the conversion element detectable by a consequent break of the sensor, which increases an electrical resistance of the sensor.

The sensor may be configured as a narrow and/or thin, for instance at most 1 μm thick and e.g. about 500 nm thick, conductive track, or with a small conductive cross section. The conductive track may extend between two electrical contact faces. The sensor may be configured enclosing a light output region or enclosing a light input region, in order to make an incipient break and/or a break of the conversion element detectable, besides a break through the conversion element. The sensor may be provided in a meandering shape and/or circumferentially parallel with respect to a principal optical axis or radially in multiple layers, in order to make a break detectable by a multiple effect, for instance a particularly clearly detectable electrical resistance increase due to a multiple break through the conductive track. The sensor may be of the SRS safety sensor type.

It is an alternative or additional refinement that the monitoring includes inductive monitoring of the at least one conductive track.

It is an alternative or additional refinement that the monitoring includes capacitive monitoring of the at least one conductive track.

The lead frame may be configured for connecting the measurement path to the measuring transducer that may be provided separately. The separated measuring transducer may not be a part of the conversion element and/or of the conversion module, although it may also be an integrated part of a lamp. The sensor, or the measurement path, may be applied in a coating fashion onto the conversion element, so that a relatively fine structure can be produced, which can be connected particularly firmly or rigidly to the conversion element. The sensor may be configured as a metallization, for instance a metallization produced by sputtering, as it is known in the art, (a fabrication technology of the semiconductor industry), which implies a series-compatible method for such fine structures. In other words, the conversion element may include a sensor and/or (passive) sensor section applied and/or deposited thereon.

The term “about” may, for example, mean that there may be a deviation in the technically conventional tolerances or of up to 5%.

The lead frame may include at least one inner or internal terminal and/or at least one outer or external terminal. In various embodiments, each internal terminal is assigned to one outer terminal. This may involve the case that, for example, in order to reduce a wiring outlay, one outer terminal is assigned to a plurality of internal terminals, as well as the case that, for example in order to increase a throughput or in order to produce a redundancy, a plurality of outer terminals are assigned to one internal terminal.

If the sensor is interconnected between at least two terminals of the lead frame, measurement may be carried out by electrical contacting or touching of the at least two terminals of the sensor. Advantageously, the sensor is electrically conductively connected indirectly or directly by means of respectively one internal terminal or by means of two internal terminals of the lead frame, which terminals are respectively assigned and therefore electrically conductively connected to one of the terminals. Soldering is a process-reliable way of producing an electrically conductive connection. For example, the sensor may be connected by means of soldered bond wires to the internal terminals. In various embodiments, the bond wires have at least the lowest conductivity of the sensor, and in preference the bond wires have a multiple, for instance one-and-a-half times, two times, five times or at least ten times the lowest conductivity of the sensor. The same may apply to a different connection technology between the sensor and the internal terminals of the lead frame.

The conversion module may include a thermal contact face, such as a thermal terminal in order to dissipate conversion heat from the conversion module, so that an optical efficiency of the conversion operation can be increased without quenching, or with at least reduced quenching. The thermal contact face may be configured for heat transfer, e.g. for heat removal from the conversion module. The thermal contact face may be provided on the conversion module, in order to ensure efficient thermal energy dissipation. The thermal contact face may be constituted by a metal layer deposited on the conversion layer or applied thereon, a metallization, in order to constitute particularly direct and thermally conductive contact. For example, a layer of a solder, such as a solder paste, may be printed on the metallization. In addition or as an alternative, a layer of a solder, such as a solder paste, may be printed on the conversion module. The solder may, for example, contain or consist of gold and/or tin. The metallization may, in order to permit efficient heat transfer, be from about 1 μm to about 10 μm thick or thin. Economically, to this end fabrication methods known for example from semiconductor fabrication may be used. The thermal contact face may be arranged enclosing an input region or enclosing an output region, in order to dissipate heat radially to all sides with respect to a principal optical axis. The thermal contact face may be wide in order to ensure uniform heat transfer. A wide thermal contact face may be at least 25 μm, e.g. at least 50 μm, e.g. at least 100 μm and e.g. at least 500 μm wide. Particularly uniform heat removal is achieved when the thermal contact face has a width of at least 33%, e.g. at least 50%, e.g. at least 75% and e.g. at least 100% of the thickness of the conversion element.

If the lead frame includes at least one internal terminal which is heat-transferably connected to the thermal contact face, a thermal mass as a heat sink may be thermally conductively connected to the conversion element with little outlay, particularly with little outlay in comparison with the prior art. The lead frame may thus itself act as a heat sink, or internal heat sink, so that a simple design with economical means can be implemented. The lead frame yields additional advantages, such as simple handleability, a high rigidity and a high strength, protection of the conversion element, standardizability of the format and associated tools, and the like.

If the internal terminal is heat-transferably connected to at least one external terminal of the lead frame, an external heat sink may be thermally conductively connected to the conversion element with little outlay, particularly with little outlay in comparison with the prior art. By means of the external terminal, it is thus possible to connect an external heat sink, such as for example a large external thermal mass or a cooled device. Thermally conductive mounting of the conversion module is facilitated.

It may be provided for the at least one thermal contact face to be arranged on a (two-dimensional) side of the conversion element, and in this case for an electrical contact face of the sensor or the electrical contact faces of the sensor to be arranged on the opposite side of conversion element. This facilitates (for example spatially, chronologically and/or process-technically) separate application or constitution, processing and/or connection of the contact faces, so that a time-sequence of individual steps for the production is achieved in order to promote the process reliability with low complexity.

The lead frame may, for example, be configured in a design with protruding terminals, in a design without protruding terminals, or with terminals arranged at least in a planar fashion or set back, or in a mixed design. The design variants will be outlined briefly below. In principle, all designs may be used.

A design may be provided having at least one external terminal which is placed, or received, at least in a planar fashion in a lead frame surface and is in particular set back. The term “terminal” or “external terminal” may also cover only a terminal section. Examples of such a design include a QFN (quad flats no leads package, or four-sided flat package without protruding leads) and a DFN (dual flat no leads package or two-sided flat package without protruding leads).

The terminals of the lead frame are preferably made of a metal, for example of a sheet metal. The terminals of the lead frame are preferably insulated from one another. In various embodiments, the lead frame is made of metallic terminals and an insulating base material, such as a plastic, for example manufactured by means of an injection-molding method or overmolding method. In various embodiments, an internal terminal is connected conductively, for instance electrically conductively or thermally conductively, to at least one external terminal. Conversely, at least one external terminal may be connected conductively, for instance electrically conductively or thermally conductively, to at least one internal terminal.

Besides the conversion element, a lead frame may contain further elements, for example optical elements and/or sensors relating to the conversion light and/or the excitation radiation, such as wavelength sensors.

A design may be provided having at least one external terminal which is at least raised and in particular protrudes. Connecting legs, which are provided for solder fastening and/or clamped fastening, are an example of this.

In a mixed design, provision may be made that different terminal types are used for different terminal objects. For instance, a different terminal type may be used for a thermal terminal than for an electrical terminal. Furthermore, a different terminal type may be used for an electrically positive terminal than for an electrically negative terminal. Furthermore, mounting orientation in the sense of rotation prevention may be provided by using different terminal types, so that it may, for example, be, unnecessary, process-reliably, to distinguish a thermal terminal from an electrical terminal, since confusion is impossible.

Independently claimable is a lead frame as described here for a conversion module as described here.

Independently claimable is also a conversion lamp having a holder for a lead frame as described here. Independently claimable is furthermore a conversion lamp having a holder for a lead frame of a conversion module as described here. The holder may be referred to as a mount. The holder may, by way of example, include internal terminals which are the mirror-image of the external terminals of the lead frame, for instance mirror-symmetrically or correspondingly arranged and/or mirror-symmetrically placed or connected. The holder may be provided for clamping fixing of the lead frame. The holder may be provided for latching fixing of the lead frame. The holder may be provided for direct fixing of the lead frame, for instance for automatically clamping and/or latching or distortingly press-fit fixing, and/or for indirect fixing of the lead frame, for instance for fixing by means of adhesive bonding, welding, a solder spot, a bolt, a wedge having a press-fit effect, a screw connection and/or the like. The lists above are exemplary and not exhaustive. The conversion lamp according to various embodiments may contain a conversion module as described here, which is preferably fixed by the holder.

The holder may in turn include external terminals and/or add-on parts. According to various embodiments, the holder includes a terminal connected to a heat sink or to a cooled device. It may also be part thereof, such as a recess in a cooling body. The cooling of a conversion module may be ensured effectively by means of this terminal.

The conversion lamp may contain further elements. One exemplary structure includes a radiation source, the holder being arranged in order to fix the conversion module at a distance from the radiation source, for instance separated in a fixed way or separated movably.

The radiation source may be a light source, although it may also at least partially emit radiation in the invisible range of the electromagnetic spectrum. The radiation source may be a laser diode or a laser diode arrangement, which may emit radiation in the wavelength range of from 400 nm to 450 nm. As an alternative, the light-emitting component may be a light-emitting diode (LED). This may be present in the form of at least one individually packaged LED or in the form of at least one LED chip, which includes one or more light-emitting diodes. A plurality of LED chips may be mounted on a common substrate (submount) and form an LED or they may be fastened individually or together for example on a printed circuit board (for example FR4, metal-core printed circuit board, etc.) (CoB=Chip on Board). The at least one LED may be equipped with at least one individual and/or shared optical unit for beam guiding, for example with at least one Fresnel lens or a collimator. Instead of or in addition to inorganic LEDs, for example based on AlInGaN or InGaN or AlInGaP, in general it is also possible to use organic LEDs (OLEDs, for example polymer OLEDs). The LED chips may be directly emissive or include an upstream phosphor. The LEDs may be configured in the form of micro-LEDs. The emission wavelengths of light-emitting components may lie in the ultraviolet, visible or infrared spectral ranges. The light-emitting components may additionally be provided with their own converter. In various embodiments, the LED chips emit white light in the standardized ECE white area of the automobile industry, for example produced by a blue emitter and a yellow/green converter. Exclusion of a particular radiation source type is not intended. The term “lamp” is also not intended to exclude radiation outside the visible range. The radiation source may have a rotationally symmetrical or a rotationally nonsymmetrical emission characteristic.

Provided according to various embodiments and independently claimable is also a production method for a conversion module. The method includes at least providing a lead frame and connection. This process involves provision of a lead frame having at least one internal terminal. At least one external terminal may be provided. The terminals may be externally-internally connected in pairs, for instance conductively connected. In other regards, reference is made to the above description of the lead frame. A second process involves connection of a conversion module to the (respective) at least one internal terminal of the lead frame.

As a refinement, the connection may include soldered connection between at least one thermal contact face on the conversion element and at least one internal thermal terminal of the lead frame.

As a refinement, the connection may include soldered connection between at least one electrical contact face on the conversion element and at least one internal electrical terminal of the lead frame. This soldered connection may include soldered connection by means of a bond wire.

In various embodiments, the step of connection between the at least one thermal contact face and the at least one internal thermal terminal is carried out at least not after and e.g. before the process of connection between the at least one electrical contact face and the at least one internal electrical terminal. A method which is different, at least in respect of parameters used (time, temperature, soldering method and the like), may therefore be used in order to produce the connections of thermal connection and electrical connection. For example, when the electrical connection requires less energy input for release than the thermal connection does for connection, in an oven during the soldering it is possible to prevent particularly process-reliably that production of the thermal connection may lead to a release of the electrical connection.

As a refinement, encapsulation in order to protect at least the electrical connection, which has been produced, may be carried out after the production of the electrical connection. The encapsulation may be locally limited encapsulation, in order to avoid the influence of radiation, such as excitation radiation and/or conversion radiation.

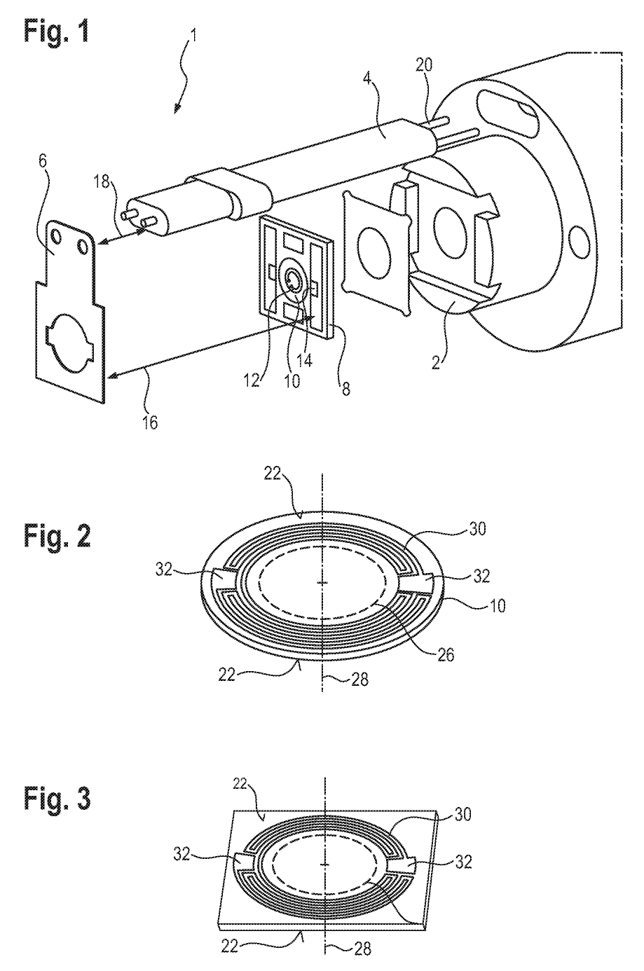

A conversion lamp 1 represented in FIG. 1 includes a housing 2, a contact pin 4, a circuit board 6 and a conversion module 8 having a conversion element 10 with an SRS sensor 12. The SRS sensor 12 is electrically conductively connected by means of a plurality of connection positions, technically known as interconnects, to conductors (not represented) for example arranged on the housing 2 and e.g. insulated from the housing 2. These connection positions are in the present case a soldered bond wire connection 14, an adhesive bond 16, a soldered connection 18 and a jack connection 20. The large number of different connection technologies entails a high outlay and high costs.

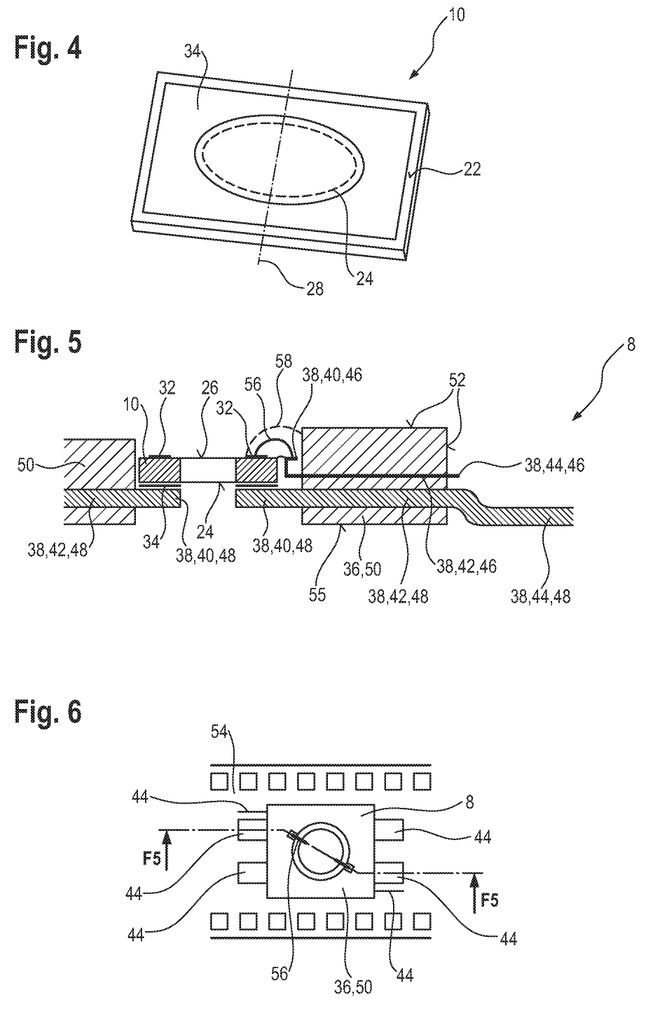

FIG. 2 to FIG. 4 show two different embodiments of a conversion element 10 according to various embodiments. Specifically, FIG. 2 shows a round conversion element 10, and FIG. 3 to FIG. 4 show a polygonal, for instance rectangular, in this case square, conversion element 10. The conversion elements 10 are two-dimensional components, which extend along an essentially flat plane so that two mutually opposite two-dimensional main sides 22 are formed. Essentially centrally in the two-dimensional conversion element 10, there is an input region 24 to be exposed to excitation radiation, opposite which there is an output region 26, between which regions 24, 26 conversion of at least a part of excitation radiation primarily takes place into conversion radiation. One of the regions 24, 26, in this case the output region 26, is enclosed radially outward with respect to an optical axis 28, or principal axis, by a circumferentially meandering and radially/circumferentially overlapping conductive track 30, which electrically conductively connects two electrical contact faces 32. In various embodiments, a thermal contact region 34 is arranged on the opposite main side 22. The thermal contact region 34 may also be arranged on the same main side 22 as the conductive track 30, in which case the thermal contact region 34 may be provided radially outward in order to establish first the thermal conduction connection and then the electrical connection in an easily producible way.

FIG. 6 and the representation of FIG. 5, which is a section along “F5” in FIG. 6, show a conversion module 8 according to various embodiments including a conversion element 10 and a lead frame 36. The conversion element 10 corresponds to the embodiment of FIG. 3 to FIG. 4. The lead frame 36 includes terminals 38, which respectively include an internal terminal 40 or terminal section, a connection 42 or a connection section, and an external terminal 44 or terminal section.

The terminals 38 are electrical terminals 46 and thermal terminals 48, these terms representing a simplification: an “electrical terminal” 46 is a terminal 38 which is configured, for instance dimensioned and/or insulated, in order to transmit an electrical signal, such as a voltage or a current strength, and which can usually also transmit thermal energy; a “thermal terminal” 48 is a terminal 38 which is configured, for instance dimensioned and/or insulated, in order to transmit thermal energy, such as waste heat of the conversion element 10 generated by conversion, and which can usually also transmit an electrical signal. For example, in the present embodiment, the terminals 38 of the electrical terminal 46 kind or type and of the thermal terminal 48 kind differ primarily by dimensioning of the effective cross section, and specifically a relatively large amount of thermal energy is intended to be transmitted through the at least one thermal terminal 48, while only a relatively weak electrical current strength is intended to be transmitted through the at least two electrical terminals 46. The terminals thus do not necessarily differ in a material sense, but essentially in terms of dimensioning. In the extreme case, the terminals 46 and 48 may be formed entirely identically or entirely differently to one another.

Besides the terminals 38, the lead frame 36 contains a base body 50 made of an insulating material, such as a high-temperature thermoplastic. For example, the base body 50 is an injection-molded part which is produced by (partial) overmolding and/or encapsulation of the terminals 38. The material may be configured with the aid of the conversion operating temperature range to be expected, for example to withstand a limit temperature plus a safety margin while maintaining its properties. For example, a material which withstands 150° C. may be selected. This requirement may also be applied to the other parts and materials. In addition or as an alternative, the materials used may be suitable for vehicle construction, for instance for a temperature range of from at least −40° C. to +125° C., which may customarily occur in or at the motor compartment of a vehicle. The base body 50 may be configured in terms of its inner contour to receive the conversion element 10 i.e. in a round and/or polygonal shape, e.g. with the interconnection of a tolerance. The base body 50 is configured in terms of its outer contour 52 according to the specifications of a format.

Production manufacture of the conversion element 8 includes the following processes. First, the lead frame 36 including the terminals 38 and the base body 50 is provided, for example delivered to a machine while being fixed on a tape 54 comparable to a roll of film. In at least one parallel, upstream and/or downstream step in relation thereto, the conversion element 10 is provided by depositing the conductive track 30, with the electrical contact faces 32, in a metallizing fashion on a two-dimensional phosphor body (conversion body), and by constituting the thermal contact face 34 by printing a solder paste onto an e.g. sputtered metallization (not represented separately). As an alternative, a sputtered solder layer for eutectic soldering may advantageously be used as a thermal contact face 34 while eliminating one process step. Then, in one process, the conversion element 10 is placed in (or on) the lead frame 36, for example in a pick & place process (application method with a separation process and an arrangement process). By at least one connection step, preferably soldering in a solder oven, the thermal contact face 34 is thermally conductively connected to the internal terminals 44 of the thermal terminals 48. During the same connection step or a different, e.g. downstream, soldering connection step, the electrical contact faces 32 are connected in such a way that they can carry current and/or carry voltage by means of bond wires 56 to the internal terminals 40 of the electrical terminals 46. Subsequently, the bond wires 56 and their solder positions are covered with an encapsulation compound 58.

The third embodiment of FIG. 5 and FIG. 6 is a lead frame design having external terminals 44 which extend in a protruding fashion from the outer contour 52 and are flush in a plane with one face of the outer contour 52, in this case with a lower side of the base body 50.

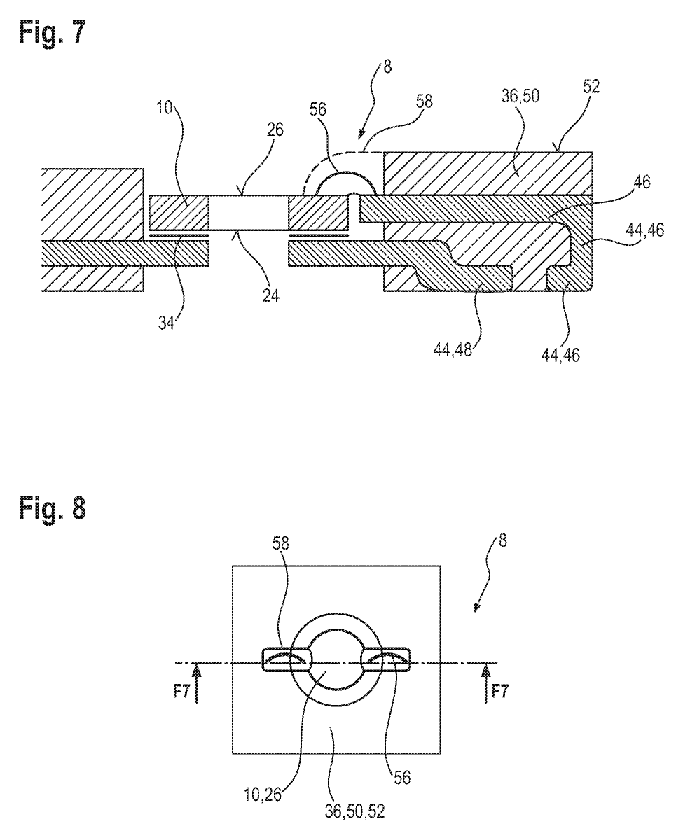

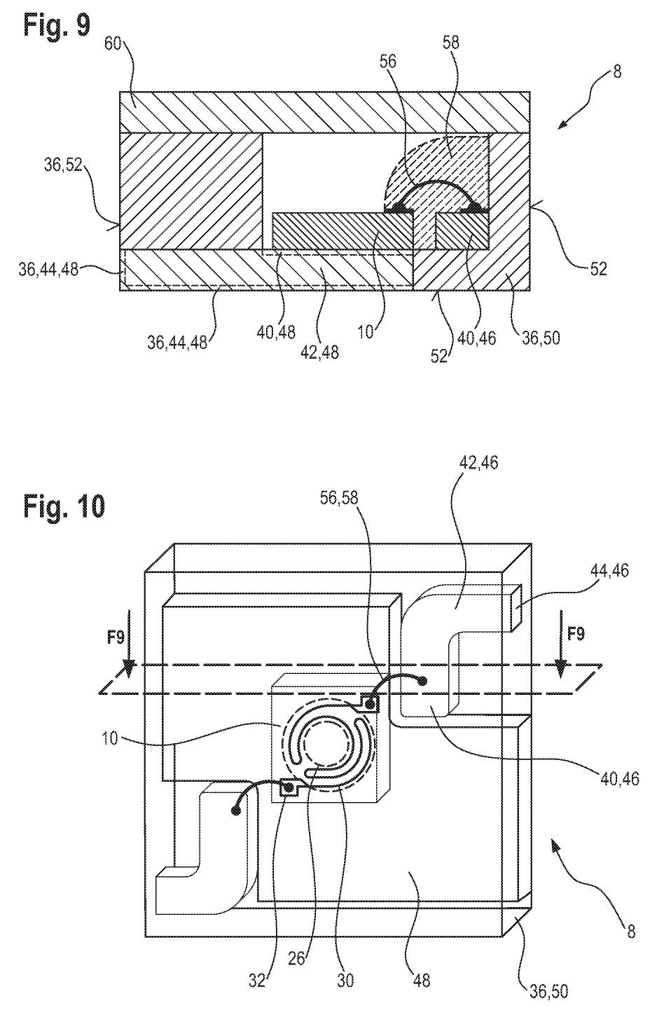

In contrast thereto, the fourth embodiment of FIG. 7 and FIG. 8 and the fifth embodiment of FIG. 9 and FIG. 10 respectively show a lead frame design having external terminals 44 placed in a planar fashion in a lead frame surface which is defined by the outer contour 52.

In this case, FIG. 8 and the representation of FIG. 7, which is a section along “F7” in FIG. 8, show a design having terminals 38 formed as curved wire.

In contrast thereto, FIG. 10 and the representation of FIG. 9, which is a section along “F9” in FIG. 10, show a design having terminals 46 and 48 which are formed from a two-dimensional semifinished product, such as a metal sheet. The sections 40, 42, 44 of the one-piece thermal terminal 48 are in this case provided as two-dimensional layers. FIG. 9 furthermore represents a covering glass lens 60 as an optional add-on component.

### LIST OF REFERENCE SIGNS

conversion lamp 1
housing 2
contact pin 4
circuit board 6
conversion module 8
conversion element 10
SRS sensor 12
bond wire connection 14
adhesive bond 16
soldered connection 18
jack connection 20
main side 22
input region 24
output region 26
optical axis 28
conductive track 30
electrical contact face 32
thermal contact face 34
lead frame 36
terminal 38
internal terminal 40
connection 42
external terminal 44
electrical terminal 46
thermal terminal 48
base body 50
outer contour 52
tape 54
bond wire 56
encapsulation compound 58
glass lens 60

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A conversion module for a conversion lamp, comprising:
a lead frame; and
a conversion element received in the lead frame.

2. The conversion module of claim 1, further comprising:
a sensor which is applied on the conversion element and is interconnected between at least two external terminals of the lead frame.

3. The conversion module of claim 2,
wherein the sensor is electrically conductively connected indirectly or directly to two internal terminals of the lead frame, which terminals are respectively electrically conductively connected to one of the external terminals.

4. The conversion module of claim 1, further comprising:
a thermal contact face provided on the conversion element.

5. The conversion module of claim 4,
wherein the lead frame comprises at least one internal terminal which is heat-transferably connected to the thermal contact face which is heat-transferably connected to at least one external terminal of the lead frame.

6. The conversion module of claim 1,
wherein the at least one thermal contact face is arranged on one side of the conversion element; and
wherein an electrical contact face of the sensor or the electrical contact faces of the sensor are arranged on the opposite side of the conversion element.

7. The conversion module of claim 1,
wherein the lead frame is provided in a configuration having at least one external terminal which is placed at least in a planar fashion in a lead frame surface.

8. The conversion module of claim 7,
wherein the lead frame is set back.

9. The conversion module of claim 1,
wherein the lead frame is provided in a configuration having at least one external terminal which is at least raised.

10. The conversion module of claim 9,
wherein the lead frame is provided in a configuration having at least one external terminal which protrudes.

11. A conversion lamp, comprising:
a holder for a lead frame of a conversion module; and
the lead frame; and
a conversion element received in the lead frame.

12. The conversion lamp of claim 11,
wherein the holder comprises a terminal thermally connected to a heat sink or to a cooled device.

13. A method of manufacturing a conversion module, the method comprising:
providing a lead frame having at least one internal terminal; and
connecting a conversion element to the at least one internal terminal of the lead frame.

14. The method of claim 13,
wherein the connection comprises soldered connection between at least one thermal contact face on the conversion element and at least one internal thermal terminal of the lead frame.

15. The method of claim 13,
wherein the connection comprises soldered connection between at least one electrical contact face on the conversion element and at least one internal electrical terminal.

16. The method of claim 13,
wherein the connecting between the at least one thermal contact face and the at least one internal thermal terminal is carried out at least not after the connecting between the at least one electrical contact face and the at least one internal electrical terminal.

17. The method of claim 16,
wherein the connecting between the at least one thermal contact face and the at least one internal thermal terminal is carried out before the connecting between the at least one electrical contact face and the at least one internal electrical terminal.

18. The method of claim 15,
wherein the encapsulating follows at least the electrical connection which has been manufactured.
